(19) United States
(12) Patent Application Publication
(10) Pub. No.: US 2015/0206663 A1
(43) Pub. Date: Jul. 23, 2015

(54) OPTO-ELECTRONIC DEVICE

(71) Applicant: SWANSEA UNIVERSITY, Swansea (GB)

(72) Inventors: Maarten Wijdekop, Velsen-Noord (NL); Daniel Thomas James Bryant, Swansea (GB); Peter Clarke Greenwood, Neath-Port Talbot (GB)

(21) Appl. No.: 14/421,395

(22) PCT Filed: Aug. 8, 2013
(86) PCT No.: PCT/EP2013/002372

§ 371 Date: Feb. 12, 2015

(30) Foreign Application Priority Data
Aug. 13, 2012 (EP) 12005840.9
Mar. 12, 2013 (EP) 13001241.2

(51) Int. Cl. H01G 9/20

(52) U.S. Cl. CPC H01G 9/2059; H01G 9/2022; H01L 51/4213

(57) ABSTRACT

The present invention relates to an opto-electronic device comprising: a first component comprising an electrode, an active layer and a first transparent conductive layer; a second component comprising a transparent electrode, and a transparent adhesive disposed between the first component and the second component, wherein the transparent electrode comprises a metal or metal alloy current collector and the transparent adhesive comprises one or more conductive components.

The present invention relates to an opto-electronic device and to a method for manufacturing the same.

Opto-electronic devices encompass organic light emitting diode (OLED) devices that convert electricity into light and photovoltaic (PV) devices that convert light into electricity e.g. dye sensitised solar cells (DSC). Such opto-electronic devices comprise at least two electrodes and an active layer suitable for converting light into electricity or vice-versa disposed therebetween. At least one of the electrodes should be transparent and both electrodes should be in electrical contact with the active layer.

For flexible opto-electronic devices the transparent ‘window’ electrode should be flexible in addition to being transparent and conductive. Such window electrodes are generally manufactured by sputtering an indium tin oxide (ITO) conductive coating onto a flexible transparent substrate such as polyethylene teraphthalate (PET) film. Sputtering of ITO onto PET films in a coating chamber generally takes place at a temperature below 150° C. under reduced pressure in order to avoid thermal degradation of the PET film. However, limiting the process temperature to below 150° C. results in an amorphous ITO coating having a reduced bulk conductivity relative to more crystalline ITO coatings that may be obtained at higher deposition temperatures e.g. 300° C. Moreover, since the process is carried out under reduced pressure, the coating chamber has to be evacuated every time a new roll of film is inserted, resulting in a batch manufacturing process that suffers regular delays. Other drawbacks of using ITO include the high start-up costs associated with installing an ITO coating facility and the cost of indium itself, which has a limited presence in the earth's crust.

It is an object of the present invention to provide a more continuous process for manufacturing opto-electronic devices. It is a further object of the present invention to improve the efficiency of large area opto-electronic devices.

The first aspect of the invention relates to an opto-electronic device comprising:
a first component comprising an electrode, an active layer and a first transparent conductive layer;
a second component comprising a transparent electrode, and
a transparent adhesive disposed between the first component and the second component, wherein the transparent electrode comprises a metal or metal alloy current collector and the transparent adhesive comprises one or more conductive components.

By providing the transparent adhesive comprising conductive components, hereafter referred to as “transparent conductive adhesive”, and the metal or metal alloy current collector, hereafter referred to as “current collector”, the inventors found that opto-electronic devices could be manufactured in a continuous in-line process without compromising the electrical resistivity of the transparent electrode and the overall efficiency of the opto-electronic device. In fact, the electrical resistivity and the overall efficiency of large area opto-electronic devices were improved when the transparent conductive adhesive and the current collector were used. This has been attributed to the current collector exhibiting an electrical resistivity several of orders of magnitude lower than that of a conductive oxide such as ITO, and the transparent conductive adhesive enhancing the electrical contact between the active material of the first component and the transparent electrode of the second component. In addition to providing electrical contact, the transparent conductive adhesive also provides mechanical adhesion between the first component and the second component.

The term ‘transparent’ generally denotes a material or layer that does not absorb a substantial amount of light in the visible portion of the electromagnetic spectrum. In the context of the present invention, transparent means that at least 50% of the light passes through the material or layer, preferably at least 70%, more preferably at least 90%.

In a preferred embodiment of the invention the surface area of the opto-electronic device is at least 1 cm², preferably at least 10 cm². While the current collector exhibits very good lateral conductivity, i.e. conductivity parallel to the plane of the device, the transparent conductive adhesive offers improved conductivity in the direction perpendicular to the plane of the device, also known as the z-direction, i.e. conduction of electrons from the active material towards the transparent electrode or from the transparent electrode to the active material. The inventors found that opto-electronic devices comprising both the current collector and the transparent conductive adhesive exhibited very good conductivity across a large surface area because resistive losses could be kept to a minimum. A large surface area may be defined as at least 1 cm². The inventors also found that good conductivity could be obtained across a device having a surface area of at least 10 cm². Preferably the surface area of the opto-electronic device is between 20 and 500 cm², more preferably between 20 and 50 cm².

In a preferred embodiment the transparent conductive adhesive is disposed between, and in contact with, a first transparent conductive layer present on the first component and a second transparent conductive layer present on the second component. The first transparent conductive layer and the second transparent conductive layer were initially provided to enhance the lateral conductivity within the opto-electronic device. However, it was found that conductivity of the transparent conductive adhesive in the z-direction could also be improved by providing the first conductive layer and the second conductive layer either side of transparent conductive adhesive.

In a preferred embodiment of the invention the first component comprises an electrode, an active layer and a first transparent conductive layer for facilitating the injection of electrons into the active layer. In this device configuration, the transparent conductive adhesive is disposed between, and in contact with the first transparent conductive layer and the transparent electrode of the second component. When a metallic grid was used as the transparent electrode, it was found that sufficient conductivity in the z-direction could be obtained even when the second transparent conductive layer was absent from the second component of the opto-electronic device. Micro-grids were particularly preferred. The inventors also found that the first and second transparent conductive layers were sufficiently adhesive and therefore it was not necessary for either layer to comprise an adhesive material, e.g. sorbitol. The first and second transparent conductive layers are therefore distinct from the transparent conductive adhesive in that these layers are provided without an adhesive material.

In a preferred embodiment of the invention the first and/or second transparent conductive layer comprises a conductive polymer, preferably one or more of:
(i) poly(3,4-ethylenedioxythiophene):poly(styrenesulfonate),hereafter referred to as “PEDOTPSS”, and/or derivatives thereof
(ii) polythiophenes and/or derivatives thereof
(iii) polyanilines and/or derivatives thereof
(iv) polypyroles and/or derivatives thereof

The inventors found that the above conductive polymers were very suitable for enhancing both the lateral conductivity of the opto-electronic device and the conductivity in the z-direction. Conductive polymers such as PEDOT:PSS and/or derivatives thereof are particularly preferred for this purpose.

With respect to the function of the first transparent conductive layer, its purpose is to increase lateral conductivity and to facilitate the injection of electrons into the active layer, i.e. it acts as an electron injection layer. When the first transparent conductive layer comprises PEDOT:PSS inks, good adhesion and electrical contact between the first transparent conductive layer and the adjacent layer of the first component, e.g. the hole conducting layer, is obtained after removal of the solvent. Similarly, when the second transparent conductive layer comprises PEDOT:PSS inks, good adhesion between this layer and the transparent electrode is obtained. The inventors found that effective electron injection into the active layer is severely reduced when the first transparent conductive layer is absent from the opto-electronic device, resulting in low photocurrents and therefore low efficiencies.

In a preferred embodiment of the invention the dry transparent conductive adhesive comprises at least 0.3 wt %, preferably between 1 and 10 wt %, more preferably between 1 and 5 wt % of the conductive component. The inventors found that transparent conductive adhesives comprising at least 0.3 wt % of the conductive component exhibited improved conductivity in the z-direction relative to the transparent adhesive itself. When the conductive component content was increased to between 1and 5 wt % a bulk conductivity of between 0.5 and 30 Siemens/cm was obtained. A bulk conductivity of between 0.01 and 30 Siemens/cm can be sufficient for good z-conduction between the current collector and the active layer. Although the bulk conductivity of the transparent conductive adhesive can be increased further by providing 10 wt % of the conductive component, it is preferred not to exceed 10 wt % since this may result in a reduction in the transparency of the transparent conductive adhesive.

In a preferred embodiment of the invention the conductive component comprises a conductive polymer, preferably one or more of:
(i) PEDOTPSS and/or derivatives thereof.
(ii) polythiophenes and/or derivatives thereof
(iii) polyanilines and/or derivatives thereof
(iv) polypyroles and/or derivatives thereof

The inventors found that the above conductive polymers were very suitable for enhancing conductivity in the z-direction. Conductive polymers such as PEDOTPSS and/or derivatives thereof are particularly preferred for this purpose. The inventors also found that very good conductivity in the z-direction was obtained when the first and second transparent conductive layers and the transparent conductive adhesive comprised conductive polymers, preferably PEDOT:PSS and/or derivatives thereof.

Preferably the conductive component comprises an allotrope of carbon. Preferred carbon allotropes comprise carbon nanotubes, graphite, carbon black, fullerenes or mixtures thereof. Transparent conductive adhesives comprising such carbon allotropes exhibit good conductivity in the z-direction.

In a preferred embodiment of the invention the transparent conductive adhesive comprises polyacrylates and/or derivatives thereof. Such transparent adhesives exhibit very good compatibility with the conductive components, preferably conductive polymers such as PEDOT:PSS and/or derivatives thereof. Moreover, such adhesives provide a very good mechanical bond between the first component and the second component.

In a preferred embodiment of the invention the transparent conductive adhesive comprises a synthetic polymer selected from the group consisting at least of epoxy resin, ethylene-vinyl acetate, phenol formaldehyde resin, polyamide, polyester resin, polyethylene, polypropylene, polysulphides, polyurethane, polyvinyl acetate, polyvinyl alcohol, polyvinyl chloride, polyvinyl chloride emulsion, polyvinylpyrrolidone or silicone; or a natural polymer selected from the group consisting at least of latex, methyl cellulose, mucilage, starch or resorcinol resin. Such transparent adhesives provided a very good mechanical bond between the first component and the second component.

In preferred embodiment the dry film thickness of the transparent conductive adhesive is between 2 and 20 μm. It was found that a strong mechanical bond existed between the first component and the second component when the dry film thickness of the transparent conductive adhesive was at least 2 μm. It is preferred not to exceed a dry film thickness of 20 μm otherwise a loss of transparency and/or a reduction in conductivity in the z-direction may be observed.

In a preferred embodiment the current collector is a free-standing mesh or is embedded in or printed on a transparent substrate, the embedded or printed current collector comprising a pre-determined structure or pattern, preferably a striped, linear, square, rectangular, hexagonal, honeycomb or triangular structure or pattern.

Preferably the current collector is printed onto a transparent substrate, the transparent substrate optionally comprising the second transparent conductive layer. The printing of metallic inks, preferably silver or copper metallic inks, enables a fast and continuous manufacturing route. Gravure-printing, flexographic printing or screen-printing are preferred means for printing such metallic inks. Once printed, the inks can be cured in a convection oven or by electromagnetic radiation; near infrared (NIR) curing is particularly preferred.

Preferably the current collector is embedded in a transparent substrate. Transparent electrodes that are produced in this way generally have a surface that is smooth and flat, making them very suitable substrates for subsequent coating e.g. with the transparent conductive adhesive or with the second transparent conductive layer. By having a smooth and flat surface, the mechanical and electrical contact between the current collector and the subsequent coating is improved. Preferably the current collector is in the form of a grid. Since the current collector is made from a metal or a metal alloy, the current collector can also afford better bulk conductivity than conductive oxides such as ITO and cured metallic inks comprising sintered metallic particles. Preferably the embedded current collectors comprise multiple layers in order to achieve a good balance between cost, performance and durability. For instance the current collector may comprise a gold sub-layer in order to provide durability and good contact with the second transparent conducive layer, a copper sub-layer as an inexpensive bulk conductor and a nickel intermediate sub-layer to facilitate the electroplating of the copper sub-layer onto the gold sub-layer.

Preferably the current collector is in the form of a free-standing mesh. Preferably the mesh is made by weaving metal or metal alloy wires, by removing holes from a metal or metal alloy substrate e.g. steel foil or sheet, by laser or mechanical cutting, by electroplating or by 3D printing.

In a preferred embodiment of the invention the metal or metal alloy current collector comprises one or more of Au, Ag, Cu, Fe, Ni, preferably the metal alloy comprises carbon steel or stainless steel.

Preferably the first component comprises a metal or metal alloy electrode, e.g. titanium, aluminium, carbon steel or stainless steel. Preferably the electrode is a metal or metal alloy foil or sheet. Such electrodes exhibit conductivities several orders of magnitude greater than that of conventional conductive oxide electrodes such as ITO.

Preferably the first component further comprises a blocking layer between the electrode and the active layer. The purpose of such a blocking layer is to prevent electrons from the electrode recombining with holes in the active layer.

Preferably the opto-electronic device is a solid state dye sensitised solar cell (sDSC). The inventors found that the present invention increased the overall efficiency of an sDSC, especially sDSC's having a large surface area. In addition, sDSC's avoid issues associated with the sealing of triiodide/iodide electrolytes that are typically used in liquid DSC technology..

In a preferred embodiment of the invention the active layer comprises a photo-active material selected from the group consisting of:
(i) an organic semiconductor
(ii) a metal oxide semiconductor, optionally sensitised with a dye
(iii) a semiconductor comprising one or more of copper, indium, gallium, selenium, zinc, tin and sulphur.

Preferably the organic semiconductor comprises a mixture of poly(3-hexylthiophene) (P3HT) and a fullerene derivative such as 6,6-phenyl C61-butyric acid methylester (PCBM). Alternatively, the organic semiconductor may comprise conjugated polymers such as phthalocyanine, polyacetylene, poly(phenylene vinylene) or derivatives thereof. Preferably the metal oxide semiconductor comprises TiO₂, ZnO, SnO₂, Nb₂O₅, InO₂, SrTiO₃, NiO or mixtures thereof, with nanoparticulate TiO₂ semiconductor materials being particularly preferred since they offer the best performance. Preferred sensitising dyes comprise ruthenium complexes and phthalocyanines. Preferably semiconductor (iii) comprises Cu(InGa)Se₂ or copper, zinc, tin and sulphide. Such semiconductors shall hereafter be referred to as CIGS and CZTS semiconductors respectively. Very high efficiencies can be obtained when the photo-active material comprises CIGS or CZTS semiconductors, making such semi-conductors suitable for use in large area photovoltaic devices.

In a preferred embodiment of the invention the first component comprises a hole transport material, hereafter referred to as “hole transport material” in electrical contact with the active layer when the photo-active material comprises photo-active material (i) or (ii). It is preferred that the hole transport material is a solid-state hole transport material. Preferably the hole transport material is printed, bar-coated, doctor bladed or slot-die coated, which leads to a more efficient and robust manufacturing process. By providing solid state hole transport material on the active layer, issues associated with the sealing of liquid charge transport materials e.g. triiodide/iodide electrolytes, are avoided.

In a preferred embodiment of the invention the hole transport material comprises an organic hole transport material, preferably 2,2′,7,7-tetrakis-(N,N-di-p-methoxyphenyl-amine)9,9′-spirobifluorene, hereafter referred to as “Spiro-OMeTAD”, fullerenes or derivatives thereof. Spiro-OMeTAD is particularly preferred as an organic hole transport material since a good electrical match exists between the energy levels of Spiro-OMeTAD and the active material, particularly the energy levels of certain sensitising dyes. Moreover, a good electrical match exists between the Spiro-OMeTAD hole transport layer and PEDOT:PSS such that improved electrical conduction in the z-direction can be obtained when the first transparent conductive layer and/or the transparent conductive adhesive comprise PEDOT:PSS. From a processing perspective, the use of Spiro-OMeTAD is preferred since it may be easily coated onto the active layer, e.g. by doctor blading, bar-coating or by slot-die coating.

In a preferred embodiment of the invention the hole transport material comprises an inorganic hole transport material, preferably fluorine-doped CsSnl₃, perovskites, copper-phthalocyanine, Cul and/or their derivatives. F-doped CsSnl₃ is particularly preferred as an inorganic hole transport material since it exhibits very good conductivity and can generate electron-hole pairs by absorbing light in the infrared region of the electromagnetic spectrum. A good electrical match also exists between the energy levels of the F-doped CsSnl3 and the active layer, preferably when the active layer comprises the dye sensitised metal oxide and particularly when the dye is a ruthenium complex dye.

In a preferred embodiment of the invention the first component comprises a buffer layer in electrical contact with the active layer and optionally a conductive oxide layer on and in electrical contact with the buffer layer when the active layer comprises photo-active material (iii), preferably the buffer layer comprises CdS, ZnS, ZnO, (Zn, Mg)O, SnO₂, In₂Sn₃ or mixtures thereof. By providing the buffer layer (p-type) on the CIGS (n-type) or the CZTS (n-type) active layer a p-n junction is formed that is capable of charge separation.

The second aspect of the invention relates to a method for manufacturing an opto-electronic device, which comprises the steps of:
(i) providing a first component comprising an electrode, an active layer and a first transparent conductive layer;
(ii) providing a second component comprising a transparent electrode and a metal or metal alloy current collector;
(iii) providing a transparent adhesive on the first component and/or on the second component, the transparent adhesive comprising one or more conductive components,
(iv) drying and/or curing the transparent conductive adhesive on the first and/or second component, and
(v) laminating the first component and the second component to form the opto-electronic device.

The inventors found that by laminating the first component and the second component together, opto-electronic devices could be manufactured in a cost effective manner and in high volume. It is preferred that the transparent conductive adhesive is provided on the second component and that the second component comprising the transparent conductive adhesive is laminated onto the first component. Preferably the transparent conductive adhesive is dried and/or cured before laminating the second component on the first component. In this way damage to the active layer of the first component is prevented or at least reduced since the active layer is not subjected to the drying and/or curing cycle that is used to dry and/or cure the transparent conductive adhesive. Manufacturing opto-electronic devices according to the method of the second aspect of the invention has the further advantage that the first component and the second component can be manufactured independently and therefore the risk of damaging the active material of the first component is reduced. Damage to the active layer may be in the form of thermal degradation or chemical reactions caused by the curing and/or electroplating of the current collector. The manufacturing process is also made more continuous by replacing a conductive oxide such as ITO with the current collector since this avoids the use of non-continuous and expensive vacuum based and/or high temperature processes such as sputtering. The first transparent conductive layer and the second transparent conductive layer may also be applied by simple coating and laminating processes.

Preferably the first component comprises a blocking layer between the electrode and the active material, Preferably the blocking layer comprises a non-porous metal oxide such as TiO₂ when the opto electronic device is a solid-state dye sensitised solar cell (sDSC). Preferably the blocking layer is applied by chemical deposition methods, for example spray pyrolysis. Such a blocking layer prevents or at least reduces electrons from the electrode recombining with the “holes” of the hole transport material located in the pores of the nano-porous TiO₂ active layer.

Preferably the first component comprises a hole transport material on the active layer. Preferably the hole transport material is applied by doctor blading, roller coating, bar coating, slot die coating or by spin coating.

Preferably a first transparent conductive layer is applied on the first component and/or a second transparent conductive layer is applied on the second component, said layers preferably being applied by screen printing, gravure printing, bar-coating or doctor-blading.

Preferably the transparent conductive adhesive is applied by doctor blading, bar-coating or by roller coating, since these methods provide very good deposition control when the transparent conductive adhesive is applied as a wet film in the micrometer range. Preferably the dried transparent conductive adhesive comprises at least 0.3 wt % of the conductive component. The inventors found that providing at least 0.3 wt % of the conductive component significantly reduced the bulk resistivity of the dried transparent conductive adhesive.

The invention will be now be elucidated by referring to the non-limitative examples below.

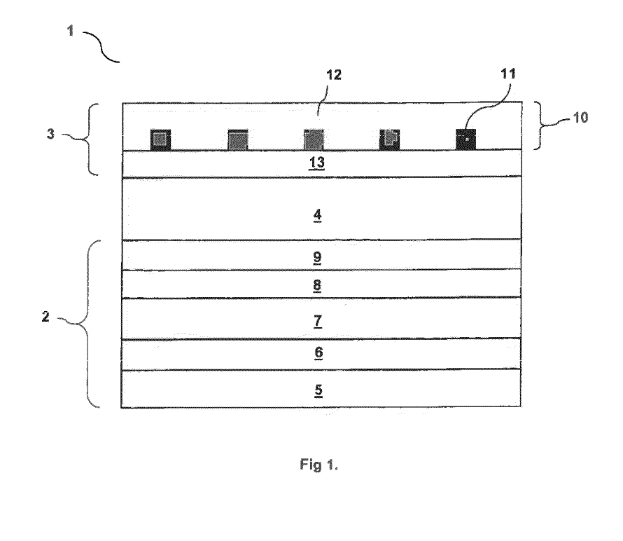

FIG. 1 represents an example of a solid state dye sensitised solar cell (sDSC) (1). The sDSC comprises a first component (2), a second component (3) and a transparent conductive adhesive disposed therebetween (4).

### EXAMPLE 1 :MANUFACTURE OF AN OPTO-ELECTRONIC DEVICE

The first component (2) of the sDSC comprises metal or metal alloy foil (5), e.g. titanium, aluminium or steel. In this example the metal foil is titanium (100 μm, grade 2). A blocking layer (6) is then applied on the titanium foil. In this example a non-porous TiO₂ blocking layer is applied on the titanium foil using spray pyrolysis. This is achieved by heating the titanium foil to 350° C. and spraying the heated foil with a 0.2 M titanium diisopropoxide bis(acetylacetonate) solution. The blocking layer obtained has a thickness between 40 and 100 nm.

An active layer (7) is then applied on the blocking layer (6). In this example a TiO₂ paste (DSL18NRT, Dyesol) is screen-printed on the blocking layer. The paste is sintered at 500° C. for 30 minutes in order to obtain a nano-porous TiO₂ layer having a dry film thickness of 2-3 microns. The coated foil is then immersed in a solution of a first dye (ID662, BASF) in ethanol (0.155 wt %) for 20 minutes at room temperature in order to sensitise the nano-porous TiO₂ with the dye. Subsequently, the coated foil is immersed in a solution of a second dye (ID176, BASF) in toluene (0.049 wt %) or in dichloro-methane (0.032 wt %) for 60 minutes at room temperature, followed by rinsing, to form a dye-sensitised nanoporous TiO₂ layer, the active layer (7).

In this example a hole transport layer (8) is applied on the active layer (7). To obtain the hole transport layer a hole transport material (HTM) solution is prepared by dissolving 2,2′,7,7-tetrakis-(N,N-di-p-methoxyphenyl-amine)9,9′-spirobifluorene (spiro-OMeTAD) in chloro-benzene (200 mg/ml). A 20 mM LiN(SO₂CF₃)₂ solution in chloro-benzene is then added to HTM solution. An oxidation agent such as vanadium oxide is then added and this HTM solution is stirred for 1-2 hours at room temperature. This HTM solution is then applied on the active layer at a wet film thickness of 70 microns by doctor blading. The coated foil is then heated for 30 seconds at 74° C. in order to drive off the solvent. Subsequent characterisation of the dried hole transport layer revealed that at least 80% of the pores of the nano-porous TiO₂ were filled with the spiro-OMeTAD hole transport material. It was also observed that the hole transport layer extended 100-500 nm above the nanoporous TiO₂.

A first transparent conductive layer (9) is provided on the hole transport layer to improve the electrical contact between the hole transport layer (8) and a transparent conductive adhesive (4). The first transparent conductive layer may be prepared by mixing a conductive Poly(3,4-alkylenedioxythiophene):polystyrene sulphonic acid (PEDOT:PSS) ink (EL-P-3145, Agfa) in a suitable solvent or solvents. This solution is then bar coated on the surface of the hole transport layer at a wet film thickness of 45microns and cured at 65° C. for 7 minutes in a dust free environment.

The second component (3) of the sDSC comprises a transparent electrode (10). The transparent electrode comprises as a current collector a square nickel grid (11) (line width 5 um, pitch 200 um) embedded in a transparent PET film (12) (Epigem Ltd). A second transparent conductive layer (13) is provided on the transparent electrode in order to improve the electrical contact between the transparent conductive adhesive and the nickel grid. The second transparent conductive layer comprises a PEDOT:PSS ink (EL-P-3145, Agfa) and was prepared in the same way as the first transparent conductive layer.

The transparent conductive adhesive (4) is then bar coated on the second transparent conductive layer (13) at a wet film thickness of 90 microns. The transparent conductive adhesive is prepared by mixing a commercially available acrylic adhesive (Styccobond F46) with a PEDOT:PSS ink (EL-P-3145, Agfa) in a 50/50 ratio by weight. This mixture is stirred for approximately two minutes and then subjected to a low pressure environment to remove entrapped air. This measured viscosity of the mixture was 12.7 Pascals at a shear rate of 1/s.

The transparent electrode (10) coated with the second transparent conductive layer (13) and the transparent conductive adhesive (4) is then subjected to a 60° C. heat treatment for fifteen minutes to remove any low boiling point solvents. The temperature is then increased to 120° C. for five minutes to remove the higher boiling solvents in the transparent conductive adhesive. After curing, the transparent conductive adhesive exhibited a bulk conductivity of 0.01-30 S/cm and a contact resistance with the cured PEDOT:PSS ink on the grid of 0.01-10 Ohm.cm₂.

The second component (3) with the cured transparent conductive adhesive (4) is then manually laminated (at room temperature with 1 bar of mechanical pressure) onto the first component (2) such that the transparent conductive adhesive (4) is in mechanical and electrical contact with the first transparent conductive layer (9) of the first component to form the sDSC (1).

To test the performance of the sDSC devices, I-V (current-voltage) measurements were taken using a class AAA Oriel Sol3A solar simulator and a Keithley Instruments Model 2400 source meter. This system uses a filtered Xenon Arc lamp and light filters to simulate sunlight equivalent to the intensity of light being produced at 1 sun (100 mW/cm2) and at a third of a sun (33 mW/cm2).

Each sDSC that was produced was tested in an identical manner, ensuring that every cell was cold and had a clean surface when it was placed in the test chamber. The cells were tested from −0.3 to 1V in order to obtain their short circuit current (J_{sc}) and the open circuit voltage (V_{oc}). The results were plotted as an I-V curve. From the obtained I-V curves, the maximum power point voltage (Vₘₚₚ), the maximum power point current (Jₘₚₚ), the efficiency, and the Fill Factor (FF) can be determined.

sDSC's A-D with varying layer structures have been manufactured according to the method of Example 1.

sDSC A comprises a transparent conductive adhesive (4) provided on the hole transport layer (8). An ‘embedded grid’ transparent electrode (10) with a second transparent conductive coating (13) is provided on the transparent conductive adhesive.

sDSC B comprises a first transparent conductive coating (9) on the hole transport material (8), a transparent conductive adhesive (4) on the first transparent conductive layer and a transparent electrode (10) on the transparent conductive adhesive.

sDSC C comprises a first transparent conductive coating (9) on the hole transport material (8), a conductive adhesive (4) and a transparent electrode (10) with a second transparent conductive coating (13). The surface area of the sDSC C device is 0.70 cm².

sDSC D comprises the same layer structure as sDSC C but has a larger surface area (22.94 cm²).

SDSC E comprises the same layer structure as sDSC B, except that the transparent conductive adhesive (4) was obtained by mixing the acrylic adhesive (Styccobond F46) with the PEDOTPSS ink (EL-P-3145, Agfa) in a 40/60 ratio by weight. This formulation (‘TCA2’) results in an improvement in the bulk conductivity properties of the transparent conductive adhesive.

The I-V data of sDSC's (A-E) are summarised in Table 1 below. In this table, the cell structure above the hole transport material (spiro-OMeTAD) is given above each data column:

TABLE 1
Results of I-V curves for sDSC (A-E) comprising one or more of a
hole transport material (HTM), a first transparent conductive coating
(1TCC), a transparent conductive adhesive (TCA or TCA2), a second
transparent conductive coating (2TCC) and an embedded grid.

| | A | B | C | D | E |
|---|---|---|---|---|---|
| | Embedded | Embedded | Embedded | Embedded | Embedded |
| | grid | grid | grid | grid | grid |
| | 2 TCC | — | 2 TCC | 2 TCC | — |
| | TCA | TCA | TCA | TCA | TCA2 |
| | — | 1 TCC | 1 TCC | 1 TCC | 1 TCC |
| | HTM | HTM | HTM | HTM | HTM |
| Voc [mV] | 360 | 620 | 640 | 640 | 730 |
| Jsc | 0.02 | 0.30 | 8.89 | 3.42 | 5.35 |
| [mA/cm²] | | | | | |
| Vmpp [mV] | 120 | 500 | 400 | 380 | 496 |
| Jmpp | 0.01 | 0.26 | 7.27 | 2.76 | 4.04 |
| [mA/cm²] | | | | | |
| Pmax [mW] | 0.00 | 0.12 | 2.04 | 24.03 | 2.17 |
| Efficiency | 0.00 | 0.13 | 2.91 | 1.05 | 2.00 |
| [%] | | | | | |
| Fillfactor | 13.10 | 69.16 | 51.13 | 47.81 | 51.30 |
| [%] | | | | | |
| Irrad. | 0.10 | 0.10 | 0.10 | 0.10 | 0.10 |
| [W/cm²] | | | | | |
| Area [cm²] | 0.90 | 0.90 | 0.70 | 22.94 | 1.08 |

SDSC C exhibits a fill factor of 51.1 %, with a Jₘₚₚ of 7.27 mA/cm² and a Vₘₚₚ of 400 mV, resulting in an overall efficiency of 2.91% under full sun irradiation. Comparison of the data of sDSC C with those of A and B indicates that the stack of the ‘embedded grid’ transparent electrode (10), the second transparent conductive coating (13), the transparent conductive adhesive (4) and the first transparent conductive coating (9) has a beneficial influence on the photocurrent and the Fill Factor of the sDSC, and therefore on its efficiency.

It can be seen from Table 1 that sDSC A, without the first transparent conductive coating (9) on the hole transport material (8), exhibits a very low photocurrent and therefore a negligible efficiency. This suggests that the first transparent conductive coating may play an important role in promoting z-conductivity in the device, by ensuring good electrical contact with the hole transport material.

sDSC B exhibits a low photocurrent and therefore a low efficiency. This suggests that the second transparent conductive coating (13) may play an important role in promoting z-conductivity in the device, by ensuring good electrical contact between the transparent electrode (10) and the conductive adhesive (4).

SDSC D has a surface area of 22.94 cm² and exhibits a fill factor of 47.81 %. Comparison of the Fill Factor of sDSC D with that of C, indicates that the stack of the ‘embedded grid’ transparent electrode (10), the second transparent conductive coating (13) and the transparent conductive adhesive (4) and the first transparent conductive coating (9) has a beneficial effect on the lateral conductivity of the counter electrode of the device, which enables the active area of the device to be increased without suffering a high increase in resistive losses.

SDSC E has a surface area of 1.08 cm² and exhibits a fill factor of 51.3%, Jₘₚₚ of 4.04 mA/cm² and a Vₘₚₚ of 496 mV, resulting in an overall efficiency of 2.00% under full sun irradiation. The fill factor is very similar to that of sDSC C, indicating that there is good electrical contact between the transparent conductive adhesive (4) and the transparent electrode (10). It is thought that the increased conductivity of the TCA2 formulation ensures good z-conductivity, even when the second transparent conductive layer (13) coating is absent from the device. However, when transparent electrodes with a coarser (printed) grid structure are used, i.e. grids with a pitch greater than 200 μm, it is expected that providing the second transparent conductive coating will improve the performance significantly.

1. Optoelectronic device comprising:
a first component comprising an electrode, an active layer and a first transparent conductive layer;
a second component comprising a transparent electrode, and
a transparent adhesive disposed between the first component and the second component,
wherein the transparent electrode comprises a metal or metal alloy current collector and the transparent adhesive comprises one or more conductive components.

2. Opto-electronic device according to claim 1, wherein the surface area of the device is at least 1 cm², preferably at least 10 cm².

3. Opto-electronic device according to claim 1, wherein the transparent conductive adhesive is disposed between, and In contact with the first transparent conductive layer present on the first component and a second transparent conductive layer present on the second component.

4. Opto-electronic device according to claim 3, wherein the first and/or second transparent conductive layer comprises a conductive polymer, preferably one or more of:
(i) poly (3,4-ethylenedioxythiophene) poly(styrenesylfonate) and/or derivatives thereof;
(ii) polythiophenes and/or derivatives thereof;
(iii) polyanilines and/or derivatives thereof.
(iv) polypyroles and/or derivatives thereof.

5. Optoelectronic device according to claim 1, wherein the transparent conductive adhesive comprises at least 0.3 wt %, preferably between 1-10 wt %, more preferably between 1-5 wt % of the conductive component.

6. Opto-electronic device according to claim 4, wherein the conductive component comprises a conductive polymer, preferably one or more of:
(v) poly (3,4-ethyienedioxythlophene) poly(styrenesulfonate) and/or derivatives thereof;
(vi) polythiophenes and/or derivatives thereof:
(vii) polyanilines and/or derivatives thereof;
(viii) polypyroles and/or derivatives thereof.

7. Opto-electronic device according to wherein the transparent conductive adhesive comprises polyacrylates and/or derivatives thereof.

8. Opto-electronic device according to claim 1, wherein the transparent conductive adhesive comprises a synthetic polymer selected from the group consisting at least of epoxy resin, ethylene-vinyl acetate, phenol formaldehyde resin, polyamide, polyester resin, polyethylene, polypropylene, polysulphides, polyurethane, polyvinyl acetate, polyvinyl alcohol, polyvinyl chloride, polyvinyl chloride emulsion, polyvinylpyrrolidone or silicone; or a natural polymer selected from the group consisting at least of latex, methyl cellulose, mucilage, starch or resorcinol resin.

9. Opto-electronic device according to claim 1, wherein the metal or metal alloy current collector Is a free-standing mesh or is embedded in or printed on a transparent substrate, the embedded or printed metal or metal alloy current collector comprising a pre-determined structure or pattern, preferably a striped, linear, square, rectangular, hexagonal or triangular structure or pattern.

10. Opto-electronic device according to claim 1, wherein the metal or metal alloy current collector comprises one or more of Au, Ag, Cu, Fe, Ni, preferably the metal alloy comprises carbon steel or stainless steel.

11. Opto-electronic device according to claim 1, wherein the active layer comprises a photo-active material selected from the group consisting of:
(i) an organic semiconductor:
(ii) a metal oxide semiconductor, optionally sensitized with a dye;
(iii) a semiconductor comprising one or more of copper, indium, gallium, selenium, zinc, tin and sulphur.

12. Opto-electronic device according to claim 11, wherein the first component comprises a hole transport material In electrical contact with the photo-active layer when the photo-active material comprises semiconductor (i) or (ii).

13. Opto-electronic device according to claim 12, wherein the hole transport material comprises 2,2′,7,7-tetrakis-(N,N-di-p-methoxyphenyl-amine) 9,9-spirobifluorene, fullerenes or their derivatives as organic hole transport materials or fluorine-doped CsSnl, perovskites, Copper-phthalocyanine, Cul or their derivatives as inorganic hole transport materials.

14. Opto-electronic device according to claim 11, wherein the first component comprises a buffer layer in electrical contact with the active layer and optionally a conductive oxide layer on and in electrical contact with the buffer layer when the active layer comprises semiconductor (iii), preferably the buffer payer comprises CdS, ZnS, ZnO, (Zn, Mg)O, SnO₂ or In₂Sn₃.

15. Method for manufacturing an opto-electronic device, which comprises the steps of:
(i) providing a first component comprising an electrode, an active layer and a first transparent conductive layer;
(ii) providing a second component comprising a transparent electrode and a metal or metal alloy current collector;
(iii) providing a transparent adhesive on the first component and/or on the second component the transparent adhesive comprising one or more conductive components.
(iv) drying and/or curing the transparent conductive adhesive on the first and/or second component, and
(v) laminating the first component and the second component to form the opto-electronic device.
